(19) United States
(12) Patent Application Publication
(10) Pub. No.: US 2006/0197082 A1
(43) Pub. Date: Sep. 7, 2006

(54) Transistor including physical property-changing layer, method of operating transistor, and method of manufacturing transistor

(75) Inventors: Choong-rae Cho, Gyeongsangnam-do (KR); In-kyeong Yoo, Gyeonggi-do (KR); Sung-il Cho, Chungcheongnam-do (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/363,235

(22) Filed: Feb. 28, 2006

(30) Foreign Application Priority Data
Mar. 2, 2005 (KR) 10-2005-0017218

(51) Int. Cl. H01L 29/18

(52) U.S. Cl. 257/42

(57) ABSTRACT

A transistor using a physical property-changing layer, a method of operating the transistor, and a method of manufacturing the transistor are provided. The transistor may include an insulation layer formed on a substrate, the first and second conductive layer patterns, the physical property-changing layer, a dielectric layer, for example, a high dielectric layer, and a gate electrode. The first and second conductive layer patterns may be spaced apart from each other on the insulation layer. The physical property-changing layer may be formed on a portion of the insulation layer between the first and second conductive layer patterns. The dielectric layer may be stacked on the physical property-changing layer and the gate electrode may be formed on the high dielectric layer.

### PRIORITY STATEMENT

This application claims the benefit of Korean Patent Application No. 10-2005-0017218, filed on Mar. 2, 2005, in the Korean Intellectual Property Office, the disclosure of which is incorporated herein in its entirety by reference.

### BACKGROUND OF THE INVENTION

1. Field of the Invention

Example embodiments of the present invention relate to a transistor and a method of manufacturing the same, and more particularly, to a transistor using a physical property-changing layer, a method of operating the transistor, and a method of manufacturing the transistor.

2. Description of the Related Art

As semiconductor technology develops, integration degree increases. As the integration degree of semiconductor devices increases, the size of semiconductor elements, e.g., field effect transistors (FETs) included in the semiconductor devices decreases. When the size of the FETs decreases, a channel length between a source electrode and a drain electrode is shortened, and a short channel effect may be introduced. Due to the short channel effect, a threshold voltage and/or mobility of a carrier of an FET may be lowered. Also, the characteristic of the FET may deteriorate by a drain induced barrier lowering (DIBL).

### SUMMARY OF THE INVENTION

Example embodiments of the present invention provide a transistor including a physical property-changing layer.

Example embodiments of the present invention provide a transistor including a physical property-changing layer capable of operating at a lower voltage and/or reducing a short channel effect.

Example embodiments of the present invention also provide a method of operating such a transistor.

Example embodiments of the present invention also provide a method of manufacturing such a transistor.

According to an example embodiment of the present invention, there is provided a transistor including an insulation layer formed on a substrate; a first conductive layer pattern and a second conductive layer pattern spaced apart from each other on the insulation layer; a physical property-changing layer formed on the insulation layer between the first and second conductive layer patterns; a dielectric layer, for example, a high dielectric layer, stacked on the physical property-changing layer; and a gate electrode formed on the high dielectric layer.

In an example embodiment the physical property-changing layer may be a material layer having a physical property that changes from metal to a semiconductor, or changes from a semiconductor to a metal depending on a potential difference between the first and second conductive layer patterns. In an example embodiment, the physical property-changing layer may be at least one selected from the group consisting of a chalcogenide material layer, a transition metal oxide layer, a synthetic material layer including transition metal oxides, an aluminum oxide layer, and a synthetic material layer including aluminum oxides.

In an example embodiment, the metal constituting the transition metal oxide layer may be at least one or more selected from the group consisting of Ti, V, Fe, Ni, Nb, and Ta.

In an example embodiment, the dielectric layer has a k value>10.

In an example embodiment, the high dielectric layer may be at least one of an Al₂O₃ layer, an HfO₂ layer, and a ZrO₂ layer.

In an example embodiment, the first and second conductive layer patterns may be at least one of a metal layer and a silicide layer that form a schottky junction with the physical property-changing layer.

According to another example embodiment of the present invention, there is provided a method of operating the transistor including: maintaining a potential difference between the first and second conductive layer patterns and applying a zero voltage or a voltage different from the zero voltage to the gate electrode.

In an example embodiment, the different voltage may be a voltage greater than the zero voltage.

In an example embodiment, the potential difference may be smaller than a minimum potential difference applied between the first and second conductive layer patterns to change the physical property-changing layer into a metal layer with a zero voltage applied to the gate electrode.

According to another example embodiment of the present invention, there is provided a method of manufacturing a transistor including: forming an insulation layer on a substrate; forming a first conductive layer pattern and a second conductive layer pattern spaced apart from each other on the insulation layer; sequentially stacking a physical property-changing layer that covers the first and second conductive layer patterns, a dielectric layer, for example, a high dielectric layer, and a gate electrode on the insulation layer; and sequentially etching part of the gate electrode, the high dielectric layer, and the physical property-changing layer to expose part of the first and second conductive layer patterns.

In an example embodiment, forming the first and second conductive layer patterns may include: forming a mask that exposes a region of the insulation layer in which the first and second conductive layer patterns are to be formed; forming a conductive layer on the exposed region of the insulation layer; and removing the mask.

In an example embodiment, the physical property-changing layer may be a material layer having a physical property that changes from metal to a semiconductor, or changes from a semiconductor to a metal depending on a potential difference between the first and second conductive layer patterns. In an example embodiment, the material layer may be at least one selected from the group consisting of a chalcogenide material layer, a transition metal oxide layer, a synthetic material layer including transition metal oxides, an aluminum oxide layer, and a synthetic material layer including aluminum oxides.

According to example embodiments of the present invention, the transistor may operate at a lower voltage, so that heat emission and/or power consumption may be reduced. Also, the short channel effect may be reduced.

### BRIEF DESCRIPTION OF THE DRAWINGS

The above and other features and advantages of example embodiments of the present invention will become more apparent by describing in detail example embodiments thereof with reference to the attached drawings in which:

FIG. 1 is a sectional view of a transistor according to an example embodiment of the present invention;

FIGS. 2 through 4 are sectional views illustrating operations of the transistor of FIG. 1;

FIG. 5 is a graph illustrating a current-voltage characteristic measured from a transistor for test manufactured for the purpose of checking the operation characteristic of the transistor of FIG. 1; and

FIGS. 6 through 8 are sectional views illustrating a method of manufacturing the transistor of FIG. 1 step by step.

### DETAILED DESCRIPTION OF EXAMPLE EMBODIMENTS OF THE INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

A transistor according to an example embodiment of the present invention will be described below.

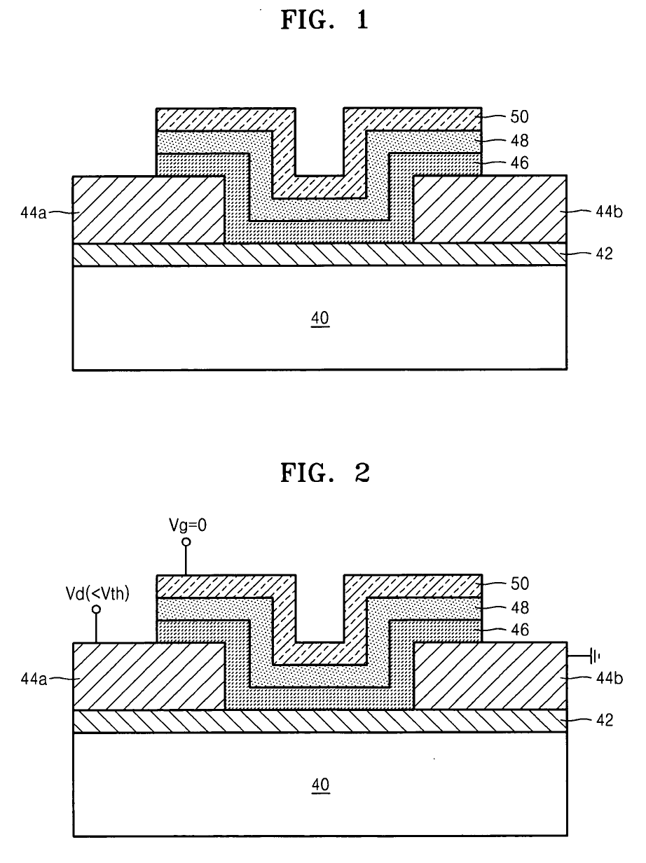

Referring to FIG. 1, an insulation layer 42 may be stacked on a substrate 40. The substrate 40 may be a semiconductor substrate doped with conductive impurities and may be a silicon substrate doped with n-type impurities, for example. The insulation layer 42 may be a thermal oxide layer, for example. The first conductive layer pattern 44a and the second conductive layer pattern 44b may be formed on the insulation layer 42. The first and second conductive layer patterns 44a and 44b may be spaced an interval from each other. One of the first and second conductive layer patterns 44a and 44b may be used as a source electrode and the other may be used as a drain electrode. The first and second conductive layer patterns 44a and 44b may be a metal layer or a silicide layer that form a schottky junction with a physical property-changing layer 46. The metal layer may be formed of Al, Ti, or Au. The silicide layer may be a PtSi layer or a NiSi₂ layer.

The physical property-changing layer 46 may be formed on a portion of the insulation layer 42 between the first and second conductive layer patterns 44a and 44b. The physical property-changing layer 46 may extend over to the upper surface of the first and second conductive layer patterns 44a and 44b. The physical property-changing layer 46 may be a metal-semiconductor (insulator)-changing material layer that changes into metal or a semiconductor (insulator) depending on an intensity of a voltage applied between the first and second conductive layer patterns 44a and 44b. The physical property-changing layer 46 may be a chalcogenide material layer, a transition metal oxide layer, or a synthetic material layer including several transition metal oxides. The physical property-changing layer 46 can be an aluminum oxide layer or a synthetic material layer thereof. The transition metal constituting the transition metal oxide layer may be at least one of Ti, V, Fe, Ni, Nb, or Ta, for example.

In example embodiments, the physical property-changing layer 46 may include chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the physical property-changing layer 46 may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the physical property-changing layer 46 may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the physical property-changing layer 46 is described above as being formed primarily of ternary phase-change chalcogenide alloys, the chalcogenide alloy of the phase change material could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂-S₂ alloy, for example.

In an example embodiment, the physical property-changing layer 46 may be made of a transition metal oxide having multiple resistance states, as described above. For example, the phase change material may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The physical property-changing layer 46 may be a chemical compound including one or more elements selected from the group consisting of S, Se, Te, As, Sb, Ge, Sn, In and Ag.

A dielectric layer, for example, high dielectric layer 48 may be formed on the physical property-changing layer 46. The dielectric layer 48 may have a k value>10. The dielectric layer 48 may be a material layer (e.g., an Al₂O₃ layer, an HfO₂ layer, or a ZrO₂ layer) that has lower reactivity with respect to the physical property-changing layer 46 and may be ultra thin film-processed. A gate electrode 50 may be formed on the high dielectric layer 48.

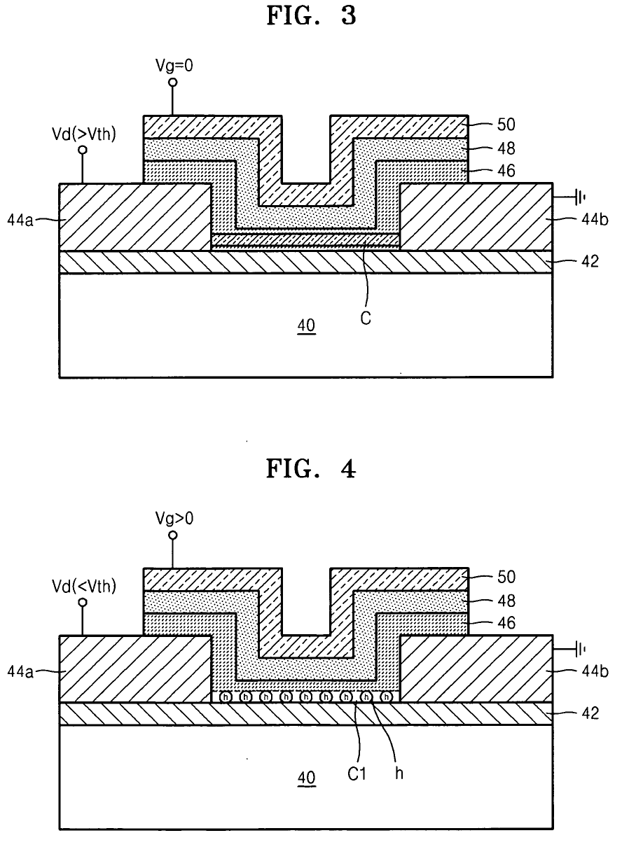

In operation, referring to FIG. 2, when a voltage Vg applied to the gate electrode 50 (referred to as a gate voltage) is maintained at a zero voltage and a potential difference Vd between the first and second conductive layer patterns 44a and 44b is maintained lower than a threshold voltage Vth between the first and second conductive layer patterns 44a and 44b, the physical property-changing layer 46 between the first and second conductive layer patterns 44a and 44b maintains the characteristic of a semiconductor or an insulator. Therefore, a channel is not formed between the first and second conductive layer patterns 44a and 44b.

Referring to FIG. 3, when the gate voltage Vg is maintained at a zero voltage and the potential difference Vd between the first and second conductive layer patterns 44a and 44b is maintained greater than the threshold voltage Vth (Vd>Vth), the physical property-changing layer 46 between the first and second conductive layer patterns 44a and 44b has the characteristic of a metal. Therefore, a channel C is formed between the first and second conductive layer patterns 44a and 44b and current flows therebetween.

Referring to FIG. 4, when the gate voltage Vg is greater than a zero voltage, a concentration of holes ‘h’ positioned at the bottom of the physical property-changing layer 46 between the first and second conductive layer patterns 44a and 44b increases. Accordingly, even though the potential difference Vd between the first and second conductive layer patterns 44a and 44b is smaller than the threshold voltage Vth, a channel ‘C1’ is formed in the physical property-changing layer 46. The above means that the threshold voltage Vth between the first and second conductive layer patterns 44a and 44b decreases when the gate voltage Vg is greater than a zero voltage.

To confirm the above result, a test transistor was manufactured and Vd and Vg under the conditions as illustrated in FIGS. 2 through 4 using the transistor, were measured.

A source electrode and a drain electrode that correspond to the first and second conductive layer patterns 44a and 44b, respectively, in the test transistor were formed of Pt having a size of 30 μm×30 μm. Also, the physical property-changing layer 46 was formed of TiAlOx having a thickness of 50 nm.

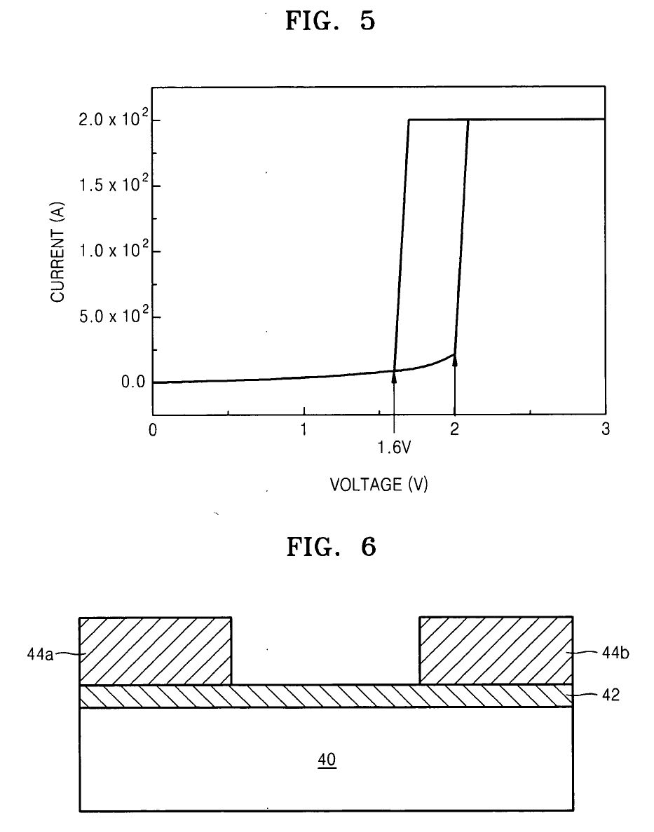

FIG. 5 is a graph illustrating a current-voltage characteristic measured for the test transistor.

FIG. 5 shows that a current flowing between the source electrode and the drain electrode in the transistor increases when a potential difference between the source electrode and the drain electrode is 1.6V and 2V. The potential difference 2V between the source electrode and the drain electrode is a threshold voltage (referred to as the first threshold voltage hereinafter) when the gate voltage Vg is a zero voltage. Also, the potential difference 1.6V between the source electrode and the drain electrode is another threshold voltage (referred to as the second threshold voltage hereinafter), which decreased as a gate voltage greater than a zero voltage is applied to the gate electrode of the transistor. Therefore, when the potential difference between the source electrode and the drain electrode is maintained at a voltage, e.g., 1.8V between the first threshold voltage and the second threshold voltage, the test transistor is turned-on in the case where a voltage greater than a zero voltage is applied to the gate electrode, and turned-off in the case where zero volts are applied to the gate electrode. Therefore, the transistor can be used as a switching device.

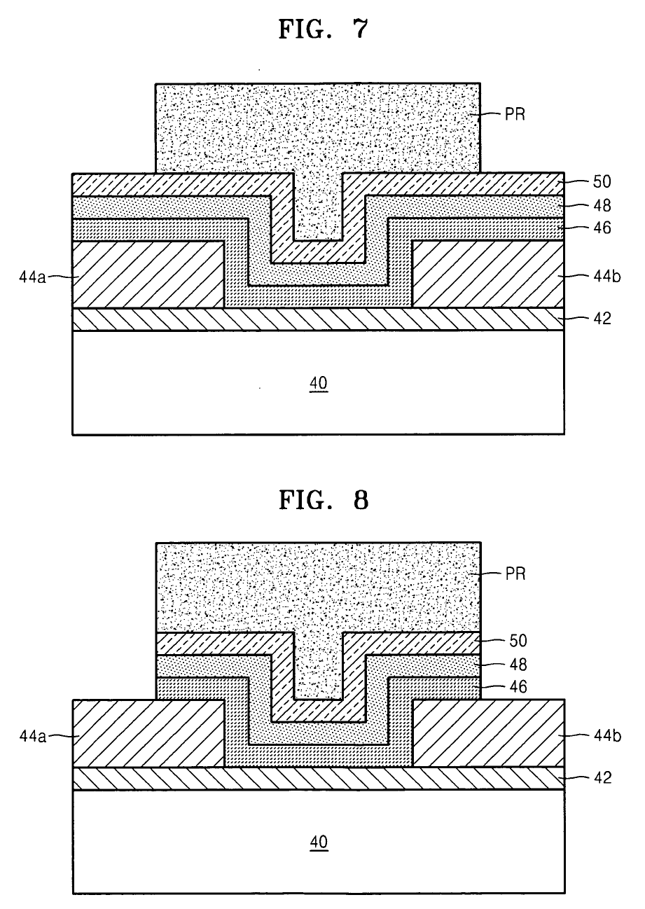

A method of manufacturing the transistor according to an example embodiment of the present invention will be described with reference to FIGS. 6 through 8.

Referring to FIG. 6, the insulation layer 42 may be formed on the substrate 40. The first and second conductive layer patterns 44a and 44b may be formed on the insulation layer 42. The first and second conductive layer patterns 44a and 44b may be spaced an interval from each other. The first and second conductive layer patterns 44a and 44b may be formed by photolithography and/or etching processes. Also, the first and second conductive layer patterns 44a and 44b may be formed using a lift-off method of forming a photosensitive layer pattern (not shown) on the insulation layer 42 between the first and second conductive layer patterns 44a and 44b, stacking a conductive layer on positions where the first and second conductive layer patterns 44a and 44b are to be formed, and removing the photosensitive layer pattern.

The substrate 40 may be formed of a semiconductor substrate doped with conductive impurities, e.g., a silicon substrate doped with n+ type impurities. The insulation layer 42 may be formed of a thermal oxide layer, e.g., an SiO₂ layer but it may be also formed of other insulation layers such as an HfO₂ layer and an SiNx layer. Also, the first and second conductive layer patterns 44a and 44b may be a metal layer or a silicide layer that form a schottky junction with the physical property-changing layer 46 that may be formed in a subsequent process. The metal layer may be formed of Al, Ti, or Au and the silicide layer may be formed of a PtSi layer or an NiSi₂ layer.

Referring to FIG. 7, the physical property-changing layer 46 covering the first and second conductive layer patterns 44a and 44b may be formed on the insulation layer 42. The physical property-changing layer 46 may be formed of a material layer having a physical property that changes from a metal to a semiconductor or from a semiconductor to a metal depending on the potential difference between the first and second conductive layer patterns 44a and 44b. The physical property-changing layer 46 may be formed of a chalcogenide material layer, a transition metal oxide layer, or a synthetic material layer including several transition metal oxides. The transition metal used for the transition metal oxide layer be at least one of Ti, V, Fe, Ni, Nb, or Ta. Also, the physical property-changing layer 46 may be formed of an aluminum oxide layer or a synthetic material layer thereof. The physical property-changing layer 46 may also be formed of any of the material mentioned above in conjunction with FIG. 1.

The high dielectric layer 48 and the gate electrode 50 may be sequentially formed on the physical property-changing layer 46. The high dielectric layer 48 may be formed of a material layer (e.g., an Al₂O₃ layer, an HfO₂ layer, or a ZrO₂ layer) that has lower reactivity with respect to the physical property-changing layer 46 and may be ultra thin film-processed. A photosensitive layer pattern PR may be formed on the gate electrode 50. The PR may cover a spaced portion between the first and second conductive layer patterns 44a and 44b and may cover part of the first and second conductive layer patterns 44a and 44b. An exposed region of the first and second conductive layer patterns 44a and 44b may be determined by the PR. After the PR is formed, an exposed region of the gate electrode 50 may be etched using the PR as a mask. The etching may be performed until the first and second conductive layer patterns 44a and 44b are exposed. As a result of the etching, the first and second conductive layer patterns 44a and 44b may be exposed as illustrated in FIG. 8. When the PR is removed after the etching, the transistor of FIG. 1 is formed.

While the present invention has been particularly shown and described with reference to example embodiments thereof, it will be understood by those of ordinary skill in the art that various changes in form and details may be made therein without departing from the spirit and scope of the present invention as defined by the following claims. For example, a person skilled in the art may form the physical property-changing layer 46 only between the source electrode and the drain electrode and may oxidize the surface of the substrate 40 at a thickness instead of forming the insulation layer 42. Also, the high dielectric layer 48 may be formed in a two- or multi-story structure. Also, the first and second conductive patterns 44a and 44b may be formed of metal having a surface on which a silicide layer is formed. Therefore, the scope of the present invention should not be determined by the example embodiment but determined by the spirit as defined by the appended claims.

As described above, the transistor according to example embodiments of the present invention may lower a minimum voltage between the source electrode and the drain electrode required for operations of the transistor by applying a voltage to the gate electrode. Therefore, heat emission and/or power consumption may be reduced because the transistor may operate at a lower voltage. Also, because the physical property-changing layer is used for the channel between the source electrode and the drain electrode, a short channel effect may be reduced.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A transistor comprising:
a substrate;
an insulation layer formed on the substrate;
a first conductive layer pattern and a second conductive layer pattern spaced apart from each other on the insulation layer;
a physical property-changing layer formed on the insulation layer between the first and second conductive layer patterns;
a dielectric layer stacked on the physical property-changing layer; and
a gate electrode formed on the dielectric layer.

2. The transistor of claim 1, wherein the physical property-changing layer is a material layer having a physical property that changes from a metal to a semiconductor, or changes from the semiconductor to the metal depending on a potential difference between the first and second conductive layer patterns.

3. The transistor of claim 1, wherein the physical property-changing layer is at least one selected from the group consisting of a chalcogenide material layer, a transition metal oxide layer, a synthetic material layer including transition metal oxides, an aluminum oxide layer, and a synthetic material layer including aluminum oxides.

4. The transistor of claim 3, wherein the metal constituting the transition metal oxide layer is at least one selected from the group consisting of Ti, V, Fe, Ni, Nb, and Ta.

5. The transistor of claim 1, wherein the dielectric layer is at least one of an Al₂O₃ layer, an HfO₂ layer, and a ZrO₂ layer.

6. The transistor of claim 1, wherein the first and second conductive layer patterns are at least one of a metal layer and a silicide layer that form a schottky junction with the physical property-changing layer.

7. The transistor of claim 6, wherein the metal layer is at least one of an Al layer, a Ti layer, and an Au layer.

8. The transistor of claim 6, wherein the silicide layer is at least one of a PtSi layer and an NiSi₂ layer.

9. A method of operating a transistor comprising:
maintaining a potential difference between first and second conductive layer patterns on an insulating layer; and
applying a zero voltage or a voltage different from the zero voltage to a gate electrode on a stack of a dielectric layer and a physical property-changing layer.

10. The method of claim 9, wherein the different voltage is a voltage greater than the zero voltage.

11. The method of claim 9, wherein the potential difference is smaller than a minimum potential difference applied between the first and second conductive layer patterns to change the physical property-changing layer into a metal layer with the zero voltage applied to the gate electrode.

12. The method of claim 9, wherein the physical property-changing layer is at least one selected from the group consisting of a chalcogenide material layer, a transition metal oxide layer, a synthetic material layer including transition metal oxides, an aluminum oxide layer, and a synthetic material layer including aluminum oxides.

13. The method of claim 12, wherein the metal constituting the transition metal oxide layer is at least one selected from the group consisting of Ti, V, Fe, Ni, Nb, and Ta.

14. The method of claim 9, wherein the first and second conductive layer patterns are at least one of a metal layer and a silicide layer that form a schottky junction with the physical property-changing layer.

15. The method of claim 14, wherein the metal layer is at least one of an Al layer, a Ti layer, and an Au layer.

16. The method of claim 14, wherein the silicide layer is at least one of a PtSi layer and an NiSi₂ layer.

17. A method of manufacturing the transistor comprising:
forming an insulation layer on a substrate;
forming a first conductive layer pattern and a second conductive layer pattern spaced apart from each other on the insulation layer;
sequentially stacking a physical property-changing layer, a dielectric layer, and a gate electrode on the insulation layer that at least partially cover the first and second conductive layer patterns; and
sequentially etching part of the gate electrode, the dielectric layer, and the physical property-changing layer to expose part of the first and second conductive layer patterns.

18. The method of claim 17, wherein forming the first and second conductive layer patterns comprises:
forming a mask that exposes a region of the insulation layer in which the first and second conductive layer patterns are to be formed;
forming a conductive layer on the exposed region of the insulation layer; and
removing the mask.

19. The method of claim 17, wherein the physical property-changing layer is a material layer having a physical property that changes from a metal to a semiconductor, or changes from the semiconductor to the metal depending on a potential difference between the first and second conductive layer patterns.

20. The method of claim 19, wherein the material layer is at least one selected from the group consisting of a chalcogenide material layer, a transition metal oxide layer, a synthetic material layer including transition metal oxides, an aluminum oxide layer, and a synthetic material layer including aluminum oxides.

21. The method of claim 20, wherein the metal constituting the transition metal oxide layer is at least one selected from the group consisting of Ti, V, Fe, Ni, Nb, and Ta.

22. The method of claim 17, wherein the high dielectric layer is at least one of an Al₂O₃ layer, an HfO₂ layer, and a ZrO₂ layer.

23. The method of claim 17, wherein the first and second conductive layer patterns are at least one of a metal layer and a silicide layer that form a schottky junction with the physical property-changing layer.
